(19) United States
(12) Patent Application Publication
(10) Pub. No.: US 2013/0113533 A1
(43) Pub. Date: May 9, 2013

(54) TEMPERATURE COMPENSATED FREQUENCY REFERENCE COMPRISING TWO MEMS OSCILLATORS

(71) Applicants: Lasse Aaltonen, Espo (FI); Jakub Gronicz, Helsinki (FI); Kari Halonen, Helsinki (FI)

(72) Inventors: Lasse Aaltonen, Espo (FI); Jakub Gronicz, Helsinki (FI); Kari Halonen, Helsinki (FI)

(21) Appl. No.: 13/642,388

(22) PCT Filed: Apr. 20, 2011
(86) PCT No.: PCT/FI2011/050360

§ 371 Date: Jan. 16, 2013

(30) Foreign Application Priority Data
Apr. 22, 2010 (FI) 20105434

(51) Int. Cl. H03L 7/08

(52) U.S. Cl. CPC H03L 7/08
USPC 327/147

(57) ABSTRACT

A temperature compensated frequency reference comprising first MEMS oscillator (MEMS1) used as frequency reference oscillator (REF) for phase locked loop, and means for temperature compensation of phase locked loop output frequency (Fout), wherein the phase locked loop comprises a second MEMS oscillator (MEMS2) used as electronically controlled oscillator (VCO) of phase locked loop.

The invention relates to PLL (Phase Locked Loop) system that uses MEMS (Micro-Electro-Mechanical Systems) reference oscillator and electronically controlled MEMS oscillator for stable low noise frequency source.

### BACKGROUND

MEMS frequency references are enabling a cheap and versatile reference frequency source to various kinds of integrated circuits. Presently the more expensive and bulky quartz references are dominant. The worst problem of MEMS oscillators is their large temperature dependency that causes a frequency error up to 0.5% within typical temperature range. The inventive solution proposed for compensating the error is a combination of electrostatic frequency control and fractional PLL. The latter involves the use of a well known PLL frequency synthesis principle and adjusting of the fractional ratio of the divider according to the temperature error of the frequency reference. Typically this is made by measuring the temperature and using some digital-signal-processing for calculation of the correction. The fractional division is used also as part of the invention with novel solution for suppressing the thermal and quantization noise without significant added production cost or complexity.

### PRIOR ART

The conventional fractional-PLL is able to create different output frequencies practically with unlimited resolution by setting the frequency division fraction. The fractional division is usually made by pseudo randomly switching the frequency division ratio so that the average output frequency of the PLL has the desired value. The frequency switching generates a large unwanted noise component in the output of the traditional integrated PLL. The temperature compensation of MEMS reference oscillator is usually made by adjusting the divider of PLL using calibration lookup table. WO2006/000611 presents one implementation of prior art solution that suffers aforementioned quantization noise.

### THE INVENTION

The aim of invention is to enable smaller and more cost effective frequency reference than quartz oscillator with good noise performance and good long term stability. The closest prior art is to compensate the output frequency of the synthesizer by altering the PLL division ratio to compensate the frequency error of the MEMS reference frequency. This leads to high amount of quantization noise that must be filtered out. This is often not tolerable, and reduction of frequency noise by filtering and by using high Q tank oscillator leads to very high operation frequency and high power consumption with integrated oscillator. Integrated LC-oscillator can not operate with less than 1 GHz frequencies. Frequencies less than 1 GHz are feasible only with external components. The aim of invention is also to reduce the operation frequency and thus lower the power consumption. Other prior art system level solutions include oven stabilization of the MEMS oscillator that is also a bulky and power consuming solution.

The solution according the invention is to use MEMS oscillator also inside PLL loop as voltage controlled oscillator (VCO). This is advantageous as implementing two MEMS oscillators is cost effective, because they can be manufactured on the same die within same process steps. The MEMS-based VCO does not need any inductor like LC oscillator and it has typically high Q-value, resulting in very low interferences in the output frequency as long as the frequency control is slow and does not contain noise at high frequencies. This is straightforward to realize by limiting the bandwidth of the PLL. Using MEMS-based VCO in PLL allows construction of frequency reference that is cheaper, smaller, and more power efficient than a quartz oscillator. The invention allows good time stability, as the critical ageing parts are operated within closed-loop electromechanical PLL, whereas the reference MEMS oscillator and temperature measurement can be realized with low drift over time.

The MEMS-resonator in the VCO requires only a limited frequency control range, as only its own temperature error needs to be compensated. It is enough, if the tuning range of the VCO allows keeping the same operation frequency over the specified temperature range. Frequency control range must also cover manufacturing tolerances. The required minimum frequency control range of VCO is only in order of one percent, which is achievable by electrostatic control of known MEMS resonators or less advantageously by heating part of the resonator.

In following the invention is described with reference to a schematic figure.

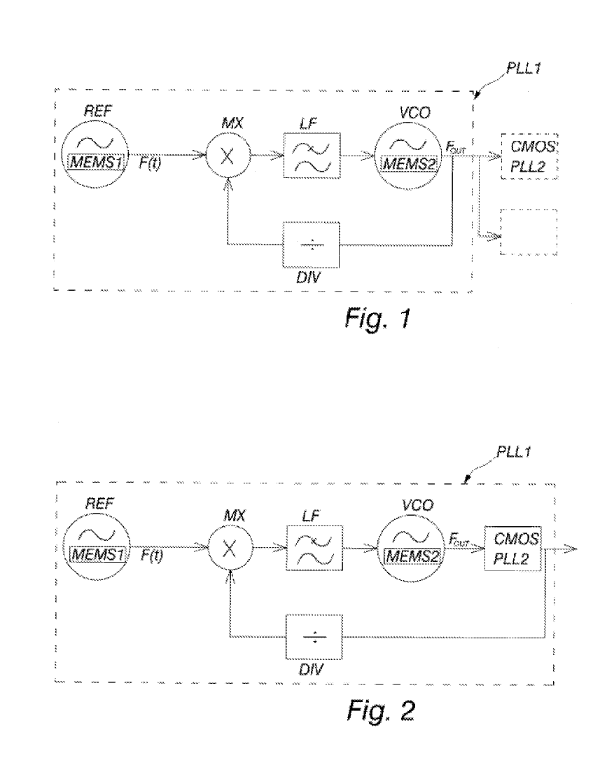

FIG. 1 presents a PLL loop oscillator for use as a frequency reference.

FIG. 2 presents a second embodiment of invention.

FIG. 1 presents a simplified block diagram of the PLL system according to the invention. The inventive system comprises two MEMS based oscillators, reference oscillator REF and PLL controlled oscillator VCO.

Reference oscillator REF comprises first MEMS-resonator based oscillator MEMS1. Reference oscillator generates frequency F(t) that is temperature dependent, and the temperature of the MEMS1 oscillator is measured for compensation. The temperature compensation is made by adjusting fractional division ratio of divider DIV, and the frequency correction of VCO is therefore adjusted as function of temperature. MX is multiplier (phase detector) or a phase-frequency detector, LF is loop filter. The principle of PLL is well known and not described here in detail. The invention is usable with several known variants of PLL, with both analogue and digital control of VCO and with different implementations of fractional frequency divider DIV, including sigma-delta-modulated control.

One preferred embodiment uses multiplier as MX, not traditional asynchronic phase-frequency-detector. The multiplier is not significantly aliasing the noise of reference, therefore there is no need for band limiting the noise of frequency reference. To suppress the phase noise of fractional divider, the loop filter is narrow band, indicating also narrow band for the PLL. The VCO is therefore conventionally in fractional divider PLL an LC-oscillator, that has high Q-value and therefore low noise also without wide-band feedback. LC-oscillator is difficult to integrate, as inductors are bulky especially at low frequencies (<GHz). Use of controllable MEMS2 in VCO instead of conventional LC-tank makes possible to implement a small integrated temperature compensated frequency reference source MEMS1 with low phase noise, operation frequency and current consumption.

The bandwidth of the MEMS VCO based PLL will become low, which however is not a significant issue when considering the use of the PLL for generating frequency reference and the temperature inflicted errors occur slowly and can be compensated for. The output of the PLL serves as reference for cascaded CMOS PLL2 in FIG. 1. The PLL2 is preferably not fractional and its bandwidth is larger for effective suppression of the phase noise and 1/F noise resulting from the VCO within the PLL2. Compared to prior art solution depicted in WO2006/000611, the solution according to the invention needs one more PLL, and one more MEMS-oscillator. Still the PLL synthesizer with frequency reference according to the invention is possible to be realized to consume less power than the prior art compensated low noise synthesizer with either quartz or MEMS reference described in WO2006/000611.

FIG. 2 present second advantageous embodiment that includes a second PLL (PLL2) inside the first PLL (PLL1) according the invention. This is done by including the PLL2 of FIG. 1 inside the control loop. The second PLL should work with integer divider and wider bandwidth of its control loop. The second PLL2 inside first PLL1 loop may be conventional CMOS-PLL that relies on low noise reference. Integer divider does not add quantization noise; therefore the second PLL2 may have wide bandwidth. The PLL2 allows use of higher frequency in the fractional divider. Higher frequency makes the fractional divider performance better and easier to optimize. Further the PLL2 may allow stepwise tuning of the output frequency, thus allowing for example compensation of manufacturing tolerances so that the controllable frequency range of the MEMS oscillator can be utilized more efficiently. This can be done for example by multiplying the frequency from MEMS2 by an integer selected between for example 190 to 210 in order to allow 10% tuning range with 0.5% steps. This way the MEMS oscillator manufacturing tolerances may be compensated separately from the temperature without adding quantization noise. This allows narrower controllable range of the MEMS2 oscillator or larger manufacturing tolerances without compromising the overall performance of the device.

The frequency of the VCO is preferably controlled by electrostatic forces that effectively change the spring constant of the mechanical MEMS-resonator in the oscillator. The VCO may be digitally controlled, which may be advantageous in full digital implementations.

Heating is second example of a possible control method of MEMS2. Heating is preferably controlled by loop filter so that the heat is generated only to part of the MEMS2. As MEMS2 works in vacuum and the heat dissipation out from the MEMS2 is happening only by radiation and conduction through the small sectional area of anchor of the spring or through the support structure of the MEMS2 resonator. The temperature of the MEMS2 needs not to be measured and only part of the MEMS2 may be heated.

The MEMS resonators may have different temperature properties, and only MEMS1 needs to be stable over time. MEMS2 may therefore be constructed with geometry optimizing the adjustability and the controllable frequency range with high enough Q-value.

The reference oscillator REF (comprising MEMS1) does not need to be adjustable, nor needs it to be exactly tuned during manufacturing, as the PLL fractional divider can be set to adjust the frequency of MEMS2. MEMS1 needs only to be stable for ageing and the temperature characteristics of the reference oscillator needs to be easy to predict and easy to measure. For example it may be enough to measure the resonance frequency and the temperature sensor reading for one or more temperatures during manufacturing process for calculating the compensation lookup-table.

Reference oscillator frequency is selected so the reference oscillator may be manufactured easily in same process with suitable properties. The reference oscillator may work with higher or lower frequency than VCO. The selection of frequencies is not a general limiting factor to the performance of the frequency reference according to the invention. VCO should work at a frequency that allows sufficient control range with CMOS operating voltage. It is also possible to use charge-pumping to increase the voltage above the nominal supply. Resonances at a few megahertz—up to 14 MHz can be realized to achieve sufficient tunability. Higher operation frequency requires either smaller gap in the capacitor, larger area, higher control voltage, or lighter seismic mass of the resonator. The usable frequencies of MEMS2 are limited by the yield and manufacturing accuracies, as it is difficult to manufacture devices with small gap in the capacitor for electrostatic control and thin structures for light weight and low mass in the resonator itself. The reference oscillator may work at for example 1 MHz. The control is made by changing the bias voltage, i.e. the spring constant, through the capacitive interface between seismic mass and the stationary bulk.

The control may use sigma-delta modulation, resulting in high amount of quantization noise before loop filter. However, as the MEMS VCO may have Q-value of order much above 1000, the phase noise is naturally suppressed by the oscillator itself, and the loop filter and control design may have loose specifications as long as the corner frequency and the noise level are sufficiently low. The loop filter is preferably narrow band, resulting in suppression of the quantization noise. The frequency is adjusted only according to the temperature; therefore very slow PLL control is in fact beneficial. The MEMS VCO itself is not limiting the speed of PLL, but the control of VCO is advantageously very slow since the temperature is a slowly-changing parameter, whereas the noise filtering benefits from a slower loop. One possible embodiment includes summing a signal to the MEMS VCO control voltage to modulate the output of MEMS VCO.

The MEMS oscillator amplitude needs to be controlled or limited; this is a general requirement for MEMS-oscillators. Electrostatic control sets further requirements on amplitude control.

The controlled oscillator VCO can be controlled also by heating part of the MEMS2 resonator structure, and therefore changing the spring coefficient of the resonator. This needs less energy than normal oven stabilization, as only a very small part of the resonator needs to be heated, and the resonator is typically in vacuum. The temperature neither needs to be uniform nor needs the temperature of the oscillator to be measured like with temperature stabilized oven. It is enough to heat the spring of the resonator and use the loop filter output to control the heating of MEMS2 resonator of controllable oscillator VCO. The heating power needed is small, as only a part of the oscillator is heated. The heated part may be formed so that the relatively small heating changes bias of spring of the harmonic oscillator or the heated part may be formed so, that the heat conducted away is small. Heating of the spring may be done by using the spring itself or part of it as resistor or by arranging a heating resistor close to the spring and heating by heat radiation or conduction. The resistor may be for example a doped area or a NP-junction.

1. A temperature compensated frequency reference comprising a first MEMS oscillator used as frequency reference oscillator for phase locked loop, and means for temperature compensation of phase locked loop output frequency, wherein the phase locked loop comprises a second MEMS oscillator used as electronically controlled oscillator of phase locked loop.

2. A temperature compensated frequency reference according to claim 1, where the temperature compensation means include means for controlling the fractional division ratio of the phase locked loop frequency divider.

3. A temperature compensated frequency reference according to claim 1, wherein the second MEMS resonator in the electronically controlled oscillator is controlled by electrostatic means or by heating means.

4. A temperature compensated frequency reference according to claim 1, wherein the first and second MEMS oscillators are formed in same die.

5. A temperature compensated frequency reference according to claim 1, wherein the output of the second MEMS oscillator is used as an input for a second phase locked loop device inside the first phase locked loop.

6. A temperature compensated frequency reference according to claim 1, wherein the output of the second MEMS resonator is used as an input for at least one second phase locked loop device outside the first phase locked loop.

7. A frequency synthesis device comprising a frequency reference according to claim 1.

8. A frequency synthesis device according to claim 7, wherein output frequency of electronically controlled oscillator may be controlled in order to tune or modulate the output frequency.

9. A frequency synthesis device according to claim 7, wherein the device comprises a temperature controlled frequency reference and one or more phase locked loops for frequency synthesis integrated in at least partly common chip.

10. A method for providing temperature stable frequency, comprising:
providing a phase locked loop with MEMS reference oscillator;
providing a phase locked loop with controllable frequency MEMS oscillator; and
controlling the phase locked loop division ratio as function of temperature or any temperature dependant magnitude in order to compensate the temperature error of the reference oscillator.
